(19) United States
(12) Patent Application Publication
(10) Pub. No.: US 2009/0045491 A1
(43) Pub. Date: Feb. 19, 2009

(54) SEMICONDUCTOR PACKAGE STRUCTURE AND LEADFRAME THEREOF

(75) Inventor: Hong-Hyoun Kim, Kyunggi-Do (KR)

Correspondence Address: J C PATENTS, INC., 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 11/839,330

(22) Filed: Aug. 15, 2007

(51) Int. Cl. H01L 23/495

(52) U.S. Cl. 257/673; 257/E23.054

(57) ABSTRACT

A semiconductor package structure including a chip and a leadframe unit is provided. The chip has an active surface and a plurality of recesses disposed thereon. The leadframe unit has at least one packaging area in which the chip is disposed. The packaging area has a plurality of leads on the peripheral portion thereof, wherein each of the leads has a first end fastened on the peripheral portion of the packaging area and a second end extending inward to the active surface of the chip. The leads have a plurality of protrusions, which are capable of being contained by the recesses, located on the second ends to electrically connect the chip and the leadframe unit.

### BACKGROUND OF THE INVENTION

1. Field of the Invention

The present invention generally relates to a semiconductor device, in particular, to a semiconductor package structure and the leadframe thereof.

2. Description of Related Art

As the development of semiconductor technology has soared in the past few decades, the size of semiconductor devices reduced dramatically while the complexity grows exponentially. Therefore, semiconductor package structures with higher die-to-package ratio are required to suit the purpose. In order to satisfy demands for miniaturization in the semiconductor industry, various packaging techniques for integrated circuits (ICs) have heretofore been developed and employed. Flip chip quad flat package no-leaded (flip chip QFN), among others, achieving miniaturization by use of flip chip and reducing the signal transmitting path by shortening the lead, is advantageous.

FIG. 1 is a cross-sectional view of a conventional flip chip QFN package. Referring to FIG. 1, the conventional flip chip QFN package 100 includes a chip 110, a leadframe 120 and a molding compound 130 covering the chip 110 and the leadframe 120. The chip 110 has an active side 110a, on which a plurality of pads 112 are disposed, and each of the pads 112 has a bump 114 disposed thereon. The leadframe 120 has a plurality of leads 122 disposed on the peripheral portion of the flip chip QFN package 100, and the chip 110 is disposed on the leadframe 120, whereas each of the pads 112 is electrically connected with one of the leads 122 through the bumps 114.

Despite the miniaturization and reduced signal transmitting path, however, flip chip QFP has its drawbacks. When disposing the chip 110 on the leadframe 120, each of the bumps 114 must be precisely positioned on the corresponding lead 122 so that the bumps 114 are to provide efficient electrical connection between the pads 112 and the leads 122, otherwise, positional error between bumps 114 and leads 122 may cause inferior electrical connection between the chip 110 and the leadframe 120, hence result in low reliability of the flip chip QFN package 100 and mediocre yield.

### SUMMARY OF THE INVENTION

Accordingly, the present invention is directed to a leadframe providing better electrical connection between the chip and the leadframe.

The present invention also provides a semiconductor package structure using the aforementioned leadframe thus the package structure has higher yield and better electrical connection between the chip and the leadframe.

The present invention provides a leadframe, suitable for carrying a chip and including at least one packaging area for the chip to be disposed thereon. The packaging area has a plurality of leads on the peripheral portion thereof, wherein each of the leads has a first end fastened on the peripheral portion of the packaging area and a second end extends inward to the peripheral portion of the chip. The leads have a plurality of protrusions located on the second ends, and the peripheral portion of the chip has a plurality of recesses capable of containing the protrusions.

According to an embodiment of the present invention, the protrusions and the leads are integrally formed from material including copper, copper alloy, or iron-nickel alloy.

According to an embodiment of the present invention, the protrusions are formed by punching one side of the leads.

According to an embodiment of the present invention, the protrusions are hollow cylinders.

According to an embodiment of the present invention, the protrusions are formed by partial etching the leads.

According to an embodiment of the present invention, the protrusions are solid cylinder.

According to an embodiment of the present invention, the packaging area further includes a die pad, and the leads are disposed around the die pad.

According to an embodiment of the present invention, the leadframe further includes a solder disposed on the protrusions.

The present invention further provides a semiconductor package structure including a chip and a leadframe. The chip has an active surface and a plurality of recesses disposed thereon. The leadframe has at least one packaging area on which the chip is disposed. The packaging area has a plurality of leads on the peripheral portion thereof, wherein each of the leads has a first end fastened on the peripheral portion of the packaging area and a second end extending inward to the chip. The leads have a plurality of protrusions, which are capable of being contained by the recesses, located on the second ends to electrically connect the chip and the leadframe.

According to an embodiment of the present invention, the protrusions and the leads are integrally formed from material including copper, copper alloy, or iron-nickel alloy.

According to an embodiment of the present invention, the protrusions are formed by punching one side of the leads.

According to an embodiment of the present invention, the protrusions are hollow cylinders.

According to an embodiment of the present invention, the protrusions are formed by partial etching the leads.

According to an embodiment of the present invention, the protrusions are solid cylinder.

According to an embodiment of the present invention, the semiconductor package structure further includes a molding compound covering the leads and the chip in the packaging area.

According to an embodiment of the present invention, the leadframe further includes a die pad, and the leads are disposed around the die pad.

According to an embodiment of the present invention, the leadframe further includes adhesive for heat conducting disposed between the die pad and the chip.

According to an embodiment of the present invention, the leadframe further includes a solder disposed on the protrusions such that the protrusions and the recesses are electrically connected.

As described above, in the present invention, each of the leads of the leadframe has a protrusion formed on the second end and the chip has a plurality of recesses. Therefore, when assembling the leadframe and the chip, the protrusions insert into the recesses and guide the leads to the corresponding recesses, even if a positional error occurs between the recesses and the leads. Thus, the tolerance of fabrication is increased and the yield of the semiconductor package structure is raised.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a conventional flip chip QFN package.

FIG. 2A is a local front elevation view of a semi-manufactured semiconductor package structure according to an embodiment of the present invention.

FIG. 2B is a cross-sectional view of a semiconductor package structure in FIG. 2A.

FIG. 2C is a cross-sectional view of a semiconductor package structure according to another embodiment in the present invention.

FIG. 3A to FIG. 3C are diagrams illustrating the process of forming the protrusions on the leads in FIG. 2B.

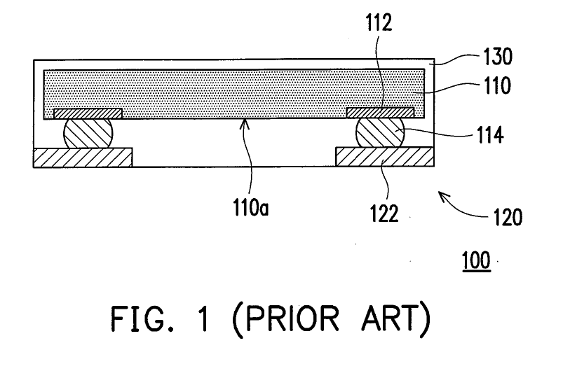

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

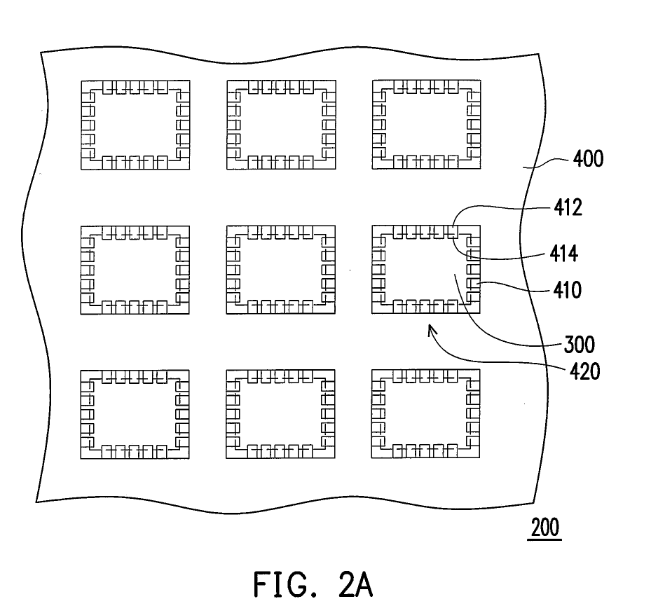

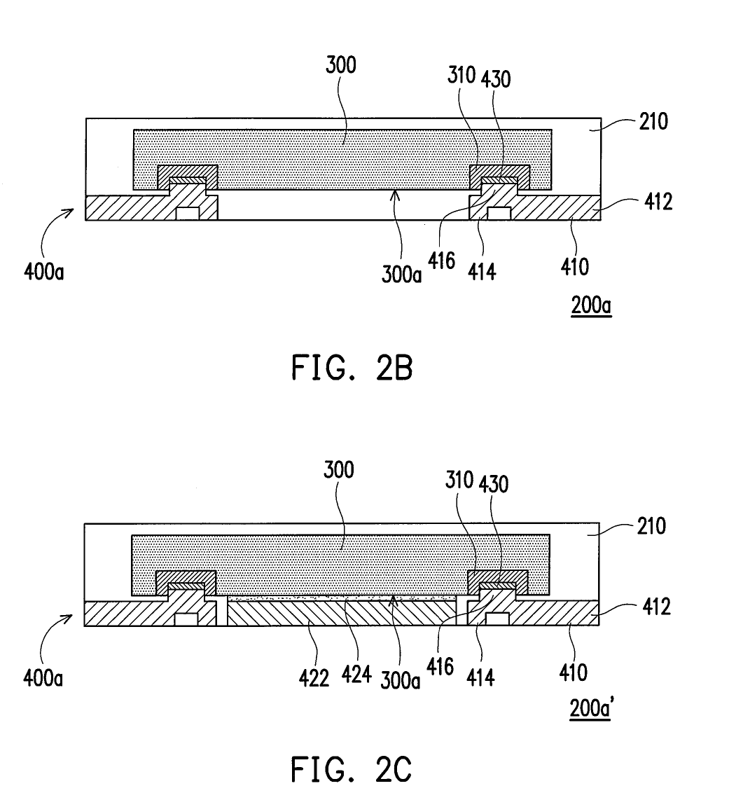

FIG. 2A is a local front elevation view of a semi-manufactured semiconductor package structure according to an embodiment of the present invention, and FIG. 2B is a cross-sectional view of a semiconductor package structure in FIG. 2A. It should be noticed that the molding compound 210 in FIG. 2B is not shown in FIG. 2A for the sake of clarity. Referring to FIG. 2A and FIG. 2B, the semi-manufactured semiconductor package structure 200 has a leadframe 400, a plurality of chips 300 having an active surface 300a and a plurality of recesses 310 disposed thereon. The recesses 310 may be made of conductive materials and used as bonding pads for electrically connecting the chip 300 and the leadframe 400. The leadframe 400 has a plurality of packaging areas 420 on which the chips 300 are disposed.

The semi-manufactured semiconductor package structure 200 may be sawed along the perimeter of each packaging area 420 to produce semiconductor package structures 200a in FIG. 2B. Each of the semiconductor package structure 200a includes a leadframe unit 400a having a plurality of leads 410 and a chip 300 disposed thereon. Each of the leads 410 has a first end 412 fastened on the peripheral portion of the packaging area 420, a second end 414 extending inward to the peripheral portion of the chip 300, and a protrusion 416 formed on the second end 414. The protrusions 416 and the leads 410 may be integrally formed from material such as copper, copper alloy, and iron-nickel alloy, and the protrusions 416 are inserted into the recesses 310 and thus electrically connect the chip 300 and the leadframe unit 400a.

Since each of the second ends 414 of the leads 410 has a protrusion 416, and the protrusions 416 are inserted into the recesses 310 when assembling, hence the protrusions 416 are capable of guiding the leads 410 to the corresponding recesses 310. Therefore, even a positional error occurs between the recesses 310 and the leads 410, the leads 410 can still be precisely positioned on the recesses 310, and thus retain good quality of electrical connection. Moreover, inserting the protrusions 416 into the recesses 310 provides supports along the direction of the leads 410, which reduces the probability of damage to the electrical connection between the recesses 310 and the leads 410 resulting from shear force. Furthermore, protrusions 416 are utilized to electrically contact the recesses 310, which replaced conventional bumps and thus reduced the cost of manufacture.

Referring to FIG. 2A and FIG. 2B, in the present embodiment, the semiconductor package structure 200a may further include a molding compound 210 covering the leads 410 and the chips 300. Although the molding compound 210 revealed in FIG. 2B covers each of the leadframe units 400a separately, the molding compound 210 may as well cover the entire leadframe units 400a in one piece before the semiconductor package structures 200a are sawed from the semi-manufactured semiconductor package structure 200.

Moreover, each of the leadframe units 400a may also include a die pad. FIG. 2C is a cross-sectional view of a semiconductor package structure according to another embodiment in the present invention. Referring to FIG. 2C, a semiconductor package structure 200a′ further has a die pad 422 on which the chip 300 is disposed, and the leads 410 are disposed around the die pad 422. The die pad 422 are exposed from the molding compound 210 to conduct the heat produced by the chips 300 to the out side of the semiconductor package structure 200a′, and each of the semiconductor package structure 200a′ may further include adhesive 424 disposed between the die pad 422 and the chip 300 to enhance the heat conductivity.

In the present embodiment, each of the leadframe units 400a further includes a plurality of solders 430, and each of the solders 430 are disposed and electrically connected between each of the protrusions 416 and the corresponding recesses 310 in order to improve the electrical connection between the protrusions 416 and the recesses 310. Nonetheless, other means can be used to enhance the electrical connection between the chip 300 and the leadframe unit 400a. For example, conductive adhesives can be disposed between the protrusions 416 and the recesses 310 to replace the solders 430.

Moreover, despite quad flat no leads (QFN) is shown to clarify the present invention, nevertheless, other package structures are also applicable, quad flat package (QFP) among them. Furthermore, although a plurality of chips 300 and packaging areas 420 are shown to demonstrate the present invention, however, other quantities of the chips 300 and the packaging areas 420 is also applicable, for example, utilizing only one packaging area 420 and one chip 300.

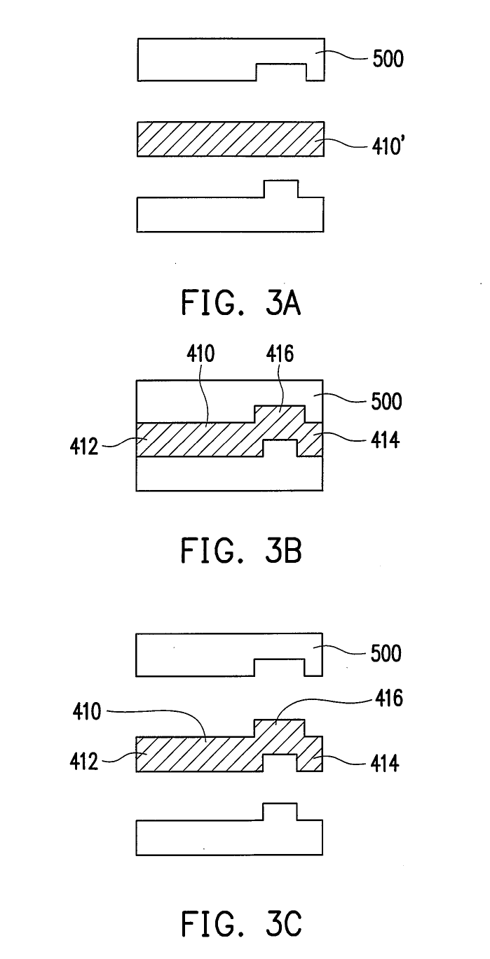

FIG. 3A to FIG. 3C are diagrams illustrating the process of forming the protrusions on the leads in FIG. 2B. Referring to FIG. 3A to 3C, the protrusions 416 may be hollow cylinders formed on one side of the second ends 414 of the leads 410 by punching the other side of the second ends 414. Each of the leads 410 may be fabricated from a flat lead 410′, as shown FIG. 3A. Then, a mold 500 may be applied to punch the lead 410′ and thus transforms the lead 410′ into lead 410 having the protrusions 416, as revealed in FIG. 3B. Finally, referring to FIG. 3C, remove the mold 500 and hence accomplish the fabricating process of the lead 410.

It is to be noted that the protrusions 416 may be formed by other means, such as partially etching the leads 410, and the protrusions 416 may be solid cylinders, formed by the remaining portions of the leads 410.

In summary, in the present invention, each of the second ends of the leads has a protrusion. When assembling, the protrusions are to be inserted into the recesses and thus the protrusions are capable of guiding the leads to the corresponding recesses. Therefore, even a positional error occurs between the recesses and the leads, the leads can still be precisely positioned on the corresponding recesses, hence the yield of the semiconductor package structure is raised.

Moreover, inserting the protrusions into the recesses provides supports along the direction of the leads, and thus strengthens the electrical connection between the leads and the recesses and therefore enhances the reliability of the package structure.

What is more, the contact between the recesses and the protrusions is achieved by utilizing protrusions instead of conventional bumps, which requires fewer steps of process, and thus leads to lower cost and shortened fabrication time.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A leadframe suitable for carrying at least one chip, comprising:
at least one packaging area, for disposing the chip therein, having a plurality of leads located on the peripheral portion thereof, in which each of the leads has a first end fastened on the peripheral portion of the packaging area and a second end extending inward to the chip,
wherein the leads have a plurality of protrusions located on the second ends, and the chip has a plurality of recesses capable of containing the protrusions.

2. The leadframe according to claim 1, wherein the protrusions and the leads are integrally formed from material including copper, copper alloy, or iron-nickel alloy.

3. The leadframe according to claim 1, wherein the protrusions are formed by punching one side of the leads.

4. The leadframe according to claim 3, wherein the protrusions are hollow cylinders.

5. The leadframe according to claim 1, wherein the protrusions are formed by partially etching the leads.

6. The leadframe according to claim 3, wherein the protrusions are solid cylinder.

7. The leadframe according to claim 1, wherein the packaging area further includes a die pad, and the leads are disposed around the die pad.

8. The leadframe according to claim 1, further comprising a plurality of solders disposed on the protrusions.

9. A semiconductor package structure, comprising:
at least one chip, having an active surface and a plurality of recesses disposed thereon; and
a leadframe unit, having a plurality of leads on the peripheral portion thereof, in which each of the leads has a first end and a second end, the second end extends inward to the active surface of the chip,
wherein the leads have a plurality of protrusions located on the second ends, and the protrusions are capable of being contained by the recesses, to electrically connect the chip and the leadframe unit.

10. The semiconductor package structure according to claim 9, wherein the protrusions and the leads are integrally formed from material including copper, copper alloy, or iron-nickel alloy.

11. The semiconductor package structure according to claim 9, wherein the protrusions are formed by punching one side of the leads.

12. The semiconductor package structure according to claim 11, wherein the protrusions are hollow cylinders.

13. The semiconductor package structure according to claim 9, wherein the protrusions are formed by partially etching the leads.

14. The semiconductor package structure according to claim 13, wherein the protrusions are solid cylinder.

15. The semiconductor package structure according to claim 9, further comprising a molding compound covering the leads and the chip.

16. The semiconductor package structure according to claim 9, wherein the leadframe unit further includes a die pad and the leads are disposed around the die pad.

17. The semiconductor package structure according to claim 16, further comprises a adhesive for heat conducting disposed between the die pad and the chip.

18. The semiconductor package structure according to claim 9, wherein the leadframe unit further comprises a plurality of solders disposed on the protrusions such that the protrusions and the recesses are electrically connected.
